(19) United States
(12) Patent Application Publication
(10) Pub. No.: US 2020/0287160 A1
(43) Pub. Date: Sep. 10, 2020

(54) DISPLAY PANEL AND DISPLAY DEVICE

(71) Applicant: Wuhan China Star Optoelectronics Semiconductor Display Technology Co., Ltd., Wuhan (CN)

(72) Inventor: Sisi ZHOU, Wuhan (CN)

(73) Assignee: Wuhan China Star Optoelectronics Semiconductor Display Technology Co., Ltd., Wuhan (CN)

(21) Appl. No.: 16/492,136

(22) PCT Filed: Apr. 8, 2019
(86) PCT No.: PCT/CN2019/081797

§ 371 Date: Sep. 8, 2019

(30) Foreign Application Priority Data
Jan. 30, 2019 (CN) 201910094259.X

(51) Int. Cl. H01L 51/52

(52) U.S. Cl. CPC H01L 51/5253; H01L 51/5293

(57) ABSTRACT

A display panel and a display device are provided. The display panel do not need to be set to a special shape to provide a region where a functional device disposed on, which is beneficial to increase the screen-to-body ratio and improve the user experience.

### FIELD OF INVENTION

The present invention relates to a field of display, and, more particularly, to a display panel and a display device.

### BACKGROUND OF INVENTION

To increase the screen-to-body ratio of an electric product, a non-display region on a display panel is compressed smaller and smaller. For instance, in a display panel of a mobile phone or a handheld terminal, functional devices of the handheld terminal, such as a front camera and an earphone, are disposed in a predetermined notch defined in a top side of a display region in order to compress the non-display region as much as possible.

FIG. 1 is a top plan view of a conventional display panel. As shown in FIG. 1, a frame 10 with a flat panel shape covers a display region 11, wherein the frame 10 is a non-display region. A notch 12 is defined in a top portion of the display region 11. Functional devices like a front camera (not shown) and an earphone (not shown) are disposed in the notch 12 in order to prevent the performance of the front camera and the earphone from being negatively influenced by the display region 11.

A disadvantage of the above structure is that a display region needs to be set to a special shape to bypass a location on which the functional devices are disposed, which breaks the integrity of the display region and reduces the screen-to-body ratio of a display panel of a handheld device.

To sum up, how to maintain the integrity of the display region and further improve the screen-to-body ratio of the electric product is a technical problem that needs to be solved at present.

### SUMMARY OF INVENTION

To solve the above technical problem, the present invention provides a display panel and a display device, which do not need to be set to a special shape to bypass a location on which functional devices are disposed, which is beneficial to increase the screen-to-body ratio and improve the user experience.

To solve the above problem, the present invention provides a display panel including: a light transmission region; a display region covering the light transmission region; a plurality of film layers, wherein at least one of the film layers has a film-free region, an orthographic projection of the film-free region overlaps with an orthographic projection of the light transmission region in a direction perpendicular to the display panel. The film layer having film-free region includes a thin film transistor layer; an organic light-emitting device layer disposed on the thin film transistor layer; and a thin film encapsulation layer covering the organic light-emitting device layer.

A width of the film-free region of the organic light-emitting device layer is larger than a width of the film-free region of the thin film encapsulation layer.

The width of the film-free region of the thin film encapsulation layer is larger than a width of the film-free region of the thin film transistor layer.

The display panel further includes a polarizer disposed on the film layers, wherein the polarizer has an opening. An orthographic projection of the opening of the polarizer overlaps with the orthographic projection of the light transmission region in the direction perpendicular to the display panel. A width of the opening of the polarizer is less than the width of the film-free region of the thin film transistor layer.

The display panel further includes a substrate, wherein the substrate has an opening. An orthographic projection of the opening of the substrate overlaps with the orthographic projection of the light transmission region in the direction perpendicular to the display panel. A width of the opening of the substrate is less than the width of the film-free region of the thin film transistor layer.

To solve the above problem, the present invention provides a display panel including: a light transmission region; a display region covering the light transmission region; a plurality of film layers, wherein at least one of the film layers has a film-free region. An orthographic projection of the film-free region overlaps with an orthographic projection of the light transmission region in a direction perpendicular to the display panel.

In one embodiment, the film layer having the film-free region is an organic light-emitting device layer.

In one embodiment, the film layers having the film-free region include an organic light-emitting device layer and a thin film encapsulation layer covering the organic light-emitting device layer. A width of the film-free region of the organic light-emitting device layer is larger than a width of the film-free region of the thin film encapsulation layer.

In one embodiment, the film layers having the film-free region include a thin film transistor layer; an organic light-emitting device layer disposed on the thin film transistor layer; and a thin film encapsulation layer covering the organic light-emitting device layer. A width of the film-free region of the organic light-emitting device layer is larger than a width of the film-free region of the thin film encapsulation layer.

In one embodiment, the width of the film-free region of the thin film encapsulation layer is larger than the width of the film-free region of the thin film transistor layer.

In one embodiment, the display panel further includes a polarizer disposed on the film layers, wherein the polarizer has an opening. An orthographic projection of the opening overlaps with the orthographic projection of the light transmission region in the direction perpendicular to the display panel. A width of the opening is less than the width of the film-free region of the thin film transistor layer.

In one embodiment, the display panel further includes a substrate with an opening, an orthographic projection of the opening overlaps with the orthographic projection of the light transmission region in the direction perpendicular to the display panel. A width of the opening is less than the width of the film-free region of the thin film transistor layer.

In one embodiment, the thin film transistor layer includes at least one metal layer. The metal layer bypasses a region corresponding to the light transmission region to form the film-free region of the thin film transistor layer.

In one embodiment, the display panel further includes a plate covering the film layers.

The present invention further provides a display device including the above display panel and a functional device disposed on a non-light-emitting side of the display panel. The functional device has a daylighting region at a side of the functional device toward the display panel. The orthographic projection of the light transmission region overlaps with an orthographic projection of the daylighting region in the direction perpendicular to the display panel.

Regarding the beneficial effect of the present invention, display panel and a display device are provided, which do not need to be set to a special shape to provide a notch, which is beneficial to increase the screen-to-body ratio and improve the user experience.

### DESCRIPTION OF DRAWINGS

FIG. 1 is a top plan view of a conventional display panel.

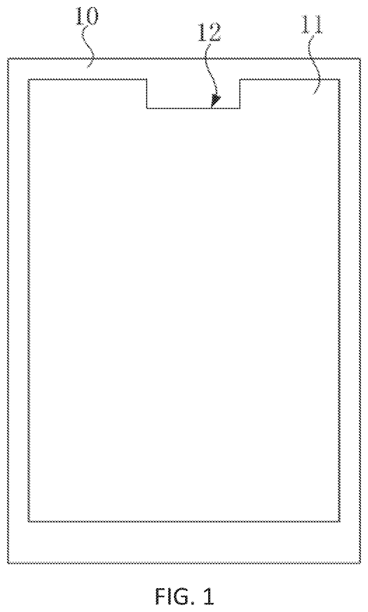

FIG. 2 is a top plan view of the first embodiment according to the display panel of the present invention.

FIG. 3 is a sectional view along a C-C line in FIG. 2.

FIG. 4 is a sectional view of the second embodiment according to the display panel of the present invention.

FIG. 5 is a sectional view of the third embodiment according to the display panel of the present invention.

FIG. 6 is a schematic view according to the display panel of the present invention.

### DETAILED DESCRIPTION OF PREFERRED EMBODIMENTS

The specific embodiments of the display panel and the display device provided by the present invention will be described in detail below with reference to the accompanying drawings.

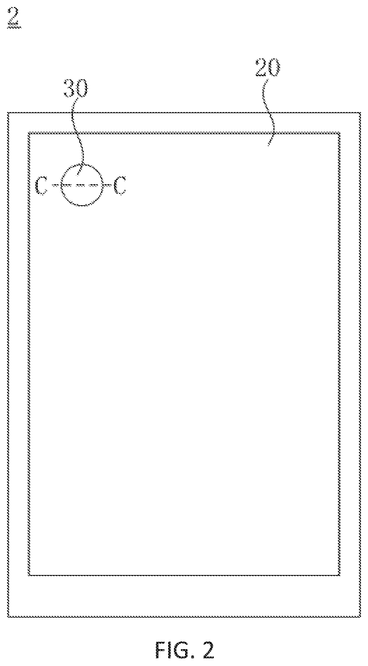

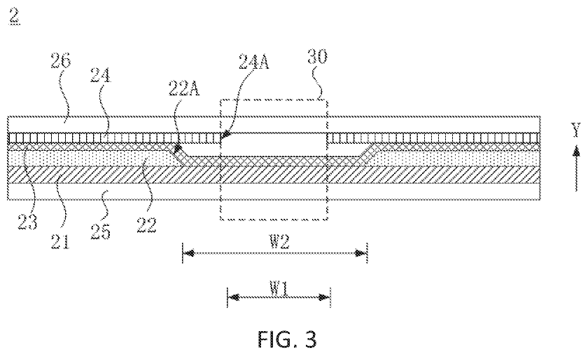

FIG. 2 is a top plan view of the first embodiment according to the display panel of the present invention. FIG. 3 is a sectional view of a C-C line in FIG. 2. As shown in FIG. 2 and FIG. 3, a display panel 2 includes a display region 20 and a light transmission region 30. The display region 20 is configured to display an image. The light transmission region 30 is configured to transmit visible light therethrough, that is, visible light can be transmitted from a light-emitting surface of the display panel 2 to a non-light-emitting surface of the display panel 2 in the light transmission region 30. The display region 20 covers the light transmission region 30, that is, an edge of the transmission layer 30 is isolated from an edge of the display region 20.

The display panel 2 includes a plurality of film layers. At least one of the film layers has a film-free region. In the present embodiment, the display panel 2 includes a thin film transistor layer 21; an organic light-emitting device layer 22 disposed on the thin film transistor layer 21; and a thin film encapsulation layer 23 covering the organic light-emitting device layer 22. The organic light-emitting device layer 22 has a film-free region 22A. The film-free region 22A is a region where the organic light-emitting device layer 22 does not form. Specifically, in the process of manufacturing the organic light-emitting device layer 22, the film-free region 22A is a predetermined region where the organic light-emitting device layer 22 does not form.

An orthographic projection of the film-free region 22A overlaps with an orthographic projection of the light transmission region 30 in a direction perpendicular to the display panel 2, in other words, the orthographic projection of the light transmission region 30 is within the orthographic projection of the film-free region 22A, which can be divided into two cases. For the first case, the orthographic projection of the film-free region 22A overlaps with the orthographic projection of the light transmission region 30 whereas for the second case, an edge of the orthographic projection of the film-free region 22A protrudes from an edge of the orthographic projection of the light transmission region 30. Specifically, according to the present invention, the orthographic projection of the film-free region 22A overlaps with the orthographic projection of the light transmission region 30, which means the orthographic projection of the film-free region 22A overlaps with the orthographic projection of the light transmission region 30 in a Y direction, or means the edge of the orthographic projection of the film-free region 22A protrudes from the edge of the orthographic projection of the light transmission region 30 in the Y direction. Since the organic light-emitting device layer 22 does not form in a region corresponding to the light transmission region 30, visible light can be transmitted from the light-emitting surface of the display panel 2 to the non-light-emitting surface of the display panel 2 in the light transmission region 30. Therefore, a functional device on the non-light-emitting surface of the display panel 2 can be irradiated by visible light.

Preferably, in the present embodiment, the display 2 further includes a polarizer 24 disposed on the film layers. Specifically, the polarizer 24 is disposed on the thin film encapsulation layer 23. The polarizer 24 has an opening 24A. The opening 24A can be formed by laser cutting in the process of manufacturing the display 2. In the direction perpendicular to the display panel 2, an orthographic projection of the opening 24A overlaps with the orthographic projection of the light transmission region 30, which means the orthographic projection of the opening 24A overlaps with the orthographic projection of the light transmission region 30 in the Y direction, or means an edge of the orthographic projection of the film-free region 24A protrudes from the edge of the orthographic projection of the light transmission region 30 in the Y direction. Since the transmission 30 is not blocked by the polarizer 24, visible light can pass through the opening 24A of the polarizer 24.

In the present embodiment, a width W1 of the opening 24A of the polarizer 24 is less than a width W2 of the film-free region 22A of the organic light-emitting device 22, thereby further preventing the organic light-emitting device 22 from being blocked by the light transmission region 30.

The display 2 further includes a substrate 25 and a plate 26. The substrate 25 is disposed underneath the thin film transistor layer 21, and the plate 26 covers the film layers. Specifically, in the present embodiment, the plate 26 covers the polarizer 24. The substrate 25 is a regular substrate like a polyimide (PI) substrate. The plate 26 is a transparent plate like a glass substrate.

In the light transmission layer 30 according to the present invention, at least one of the film layers has a film-free region. Since the transmission layer 30 is not blocked by the film layer, visible light transmittance of the layer 30 is increased. Therefore, a functional device on the non-light-emitting surface of the display panel 2 can be irradiated by visible light.

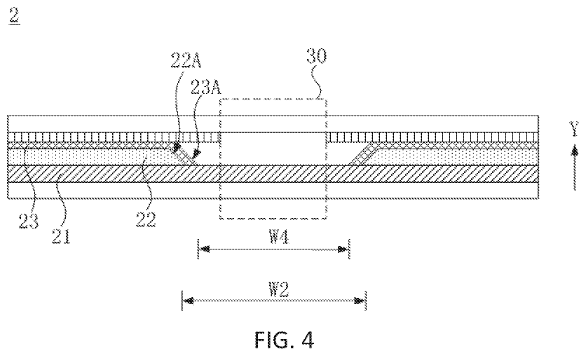

FIG. 4 is a sectional view of the second embodiment according to the display panel of the present invention. As shown in FIG. 4, in the present embodiment, the display 2 includes a thin film transistor layer 21; an organic light-emitting device layer 22 disposed on the thin film transistor layer 21; and a thin film encapsulation layer 23 covering the organic light-emitting device layer 22. The difference between the present embodiment and the first embodiment is that the organic light-emitting device layer 22 has a film-free region 22A and the thin film encapsulation layer 23 has a film-free region 23A. The organic light-emitting device layer 22 does not form in the film-free region 22A, and the thin film encapsulation layer 23 does not form in the film-free region 23A.

A width W2 of the film-free region 22A of the organic light-emitting device layer 22 is larger than a width W4 of the film-free region 23A of the thin film encapsulation layer 23. Specifically, the thin film encapsulation layer 23 is configured to cover a surface of the organic light-emitting device layer 22 and an edge of the organic light-emitting device layer 22 toward the film-free region 22A, thereby protecting a structure of the organic light-emitting device layer 22 from moisture and oxygen in the air.

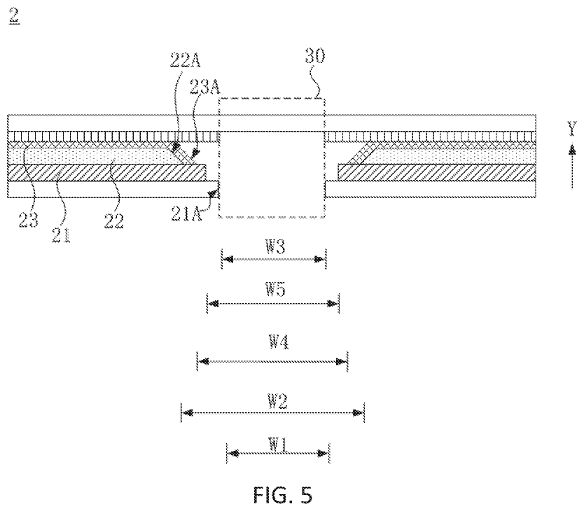

FIG. 5 is a sectional view of the third embodiment according to the display panel of the present invention. As shown in FIG. 5, in the present embodiment, the display 2 includes a thin film transistor layer 21; an organic light-emitting device layer 22 disposed on the thin film transistor layer 21; and a thin film encapsulation layer 23 covering the organic light-emitting device layer 22. The difference between the present embodiment and the first embodiment is that the organic light-emitting device layer 22 has a film-free region 22A, the thin film encapsulation layer 23 has a film-free region 23A, and the thin film transistor layer 21 has a film-free region 21A. The organic light-emitting device layer 22 does not form in the film-free region 22A, the thin film encapsulation layer 23 does not form in the film-free region 23A, and the thin film transistor layer 21 does not form in the film-free region 21A.

In the present invention, a width W2 of the film-free region 22A of the organic light-emitting device layer 22 is larger than a width W4 of the film-free region 23A of the thin film encapsulation layer 23. The width W4 of the film-free region 23A of the thin film encapsulation layer 23 is larger than a width W5 of the film-free region 21A of the thin film transistor layer 21. Therefore, a top surface, a bottom surface and an edge of the organic light-emitting device layer 22 are covered by the film layers, thereby protecting a structure of the organic light-emitting device layer 22 from moisture and oxygen in the air.

Selectively, in the present embodiment, the display 2 further includes a substrate 25 underneath the thin film transistor layer 21. The substrate 25 has an opening 25A. In a direction perpendicular to the display panel 2, an orthographic projection of the opening 25A overlaps with an orthographic projection of the light transmission region 30, which means the orthographic projection of the opening 25 of the substrate 25 overlaps with the orthographic projection of the light transmission region 30 in a Y direction, or means an edge of the orthographic projection of the opening 25A of the substrate 25 protrudes from the edge of the orthographic projection of the light transmission region 30 in the Y direction. Since the transmission 30 is not blocked by the substrate 25, visible light can pass through the opening 25A of the substrate 25.

In the present embodiment, a width W1 of an opening 24A of the polarizer 35 is less than the width W2 of the film-free region 22A of the organic light-emitting device layer 22, thereby further preventing the light transmission region 30 from being blocked by the organic light-emitting device layer 22. A width W3 of the opening 25A of the substrate 25 is less than the width W2 of the film-free region 22A of the organic light-emitting device layer 22, thereby further preventing the light transmission region 30 from being blocked by the organic light-emitting device layer 22. The opening 25A of the substrate 25 and the opening 24A of the polarizer 24A can be formed simultaneously by laser cutting in a process of manufacturing the display panel 2. Therefore, the width W3 of the opening 25A of the substrate 25 is equal to the width W1 of the opening 24A of the polarizer 24.

Selectively, in the present embodiment, the width W1 of the opening 24A of the polarizer 24 is less than a width W5 of the film-free region 21A of the thin film transistor layer 21. The width W3 of the opening 25A of the substrate 25 is less than the width W5 of the film-free region 21A of the thin film transistor layer 21. As a result, the transmission region 30 is not blocked by the film layers of the display panel 2.

The thin film transistor layer 21 has a regular structure which can be formed by a combination of at least one metal layer (not shown) and at least one insulating layer (not shown). In the present embodiment, the metal layer bypasses a region corresponding to the light transmission region 30 to form the film-free region 21A of the thin film transistor layer 21. Since the insulating layer is made of transparent materials, visible light can pass through the insulating layer. Because visible light can't pass through the metal layer, the film-free region 21A is not provided with the metal layer but the insulating layer to prevent visible light from being blocked by the metal layer. In another embodiment according to the present invention, neither the metal layer nor the insulating layer is provided by the film-free region 21A, thereby further increasing visible light transmittance of the light transmission 30.

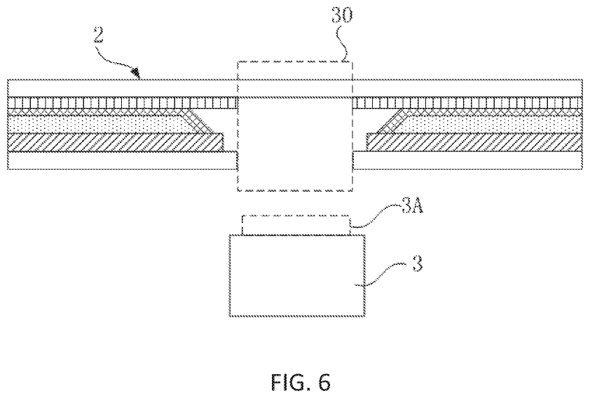

The present invention further provides a display device. FIG. 6 is a schematic view according to the display panel of the present invention. As shown in FIG. 6, the display device of the present invention includes the above display panel 2 and a functional device 3. The functional device 3 is disposed on a non-light-emitting side of the display 2. A daylighting region 3A is located on a side of the functional device 3 toward the display 2. In a direction perpendicular to the display panel 2, an orthographic projection of the light transmission 30 overlaps with an orthographic projection of the daylighting region 3A. Specifically, in the present embodiment, the functional device 3 is a camera component, and the daylighting region 30 is a lens of the camera component. An orthographic projection of the transmission 30 overlaps with an orthographic projection of the daylighting region 30, thereby ensuring the intensity of visible light entering the lens. In other embodiment of the present invention, the functional device 3 can also be other structures that need visible light, which is not limited in the present invention.

The above description is only a preferred embodiment of the present invention, and it should be noted that those skilled in the art can also make several improvements and modifications without departing from the principles of the present invention. The improvements and the modifications should also be considered as the scope of the present invention.

The present invention can be manufactured and used in the industry, so it possesses industrial practicability.

What is claimed is:

1. A display panel, comprising:
a light transmission region;
a display region covering the light transmission region;
a plurality of film layers, wherein at least one of the film layers has a film-free region, an orthographic projection of the film-free region overlaps with an orthographic projection of the light transmission region in a direction perpendicular to the display panel, the film layer having film-free region comprises a thin film transistor layer, an organic light-emitting device layer disposed on the thin film transistor layer, and a thin film encapsulation layer covering the organic light-emitting device layer;
wherein a width of the film-free region of the organic light-emitting layer is larger than a width of the film-free region of the thin film encapsulation layer, and the width of the film-free region of the thin film encapsulation layer is larger than a width of the film-free region of the thin film transistor layer;
a polarizer disposed on the film layers, wherein the polarizer has an opening, an orthographic projection of the opening of the polarizer overlaps with the orthographic projection of the light transmission region in the direction perpendicular to the display panel, a width of the opening of the polarizer is less than the width of the film-free region of the thin film transistor layer; and
a substrate, wherein the substrate has an opening, an orthographic projection of the opening of the substrate overlaps with the orthographic projection of the light transmission region, a width of the opening of the substrate is less than the width of the film-free region of the thin film transistor layer.

2. The display panel of claim 1, wherein the thin film transistor layer comprises at least one metal layer, the metal layer bypasses a region corresponding to the transmission region to form the film-free region of the thin film transistor layer.

3. The display panel of claim 1, wherein the display panel further comprises a plate covering the film layers.

4. A display panel, comprising:
a light transmission region;
a display region covering the light transmission region;
a plurality of film layers, wherein at least one of the film layers has a film-free region, an orthographic projection of the film-free region overlaps with the orthographic projection of the light transmission region in the direction perpendicular to the display panel.

5. The display panel of claim 4, wherein the film layer having the film-free region is an organic light-emitting layer.

6. The display panel of claim 4, wherein the film layers having the film-free region comprise an organic light-emitting device layer and a thin film encapsulation layer covering the organic light-emitting device layer, a width of the film-free region of the organic light-emitting device layer is larger than a width of the film-free region of the thin film encapsulation layer.

7. The display panel of claim 4, wherein the film layers having the film-free region comprise a thin film transistor layer, an organic light-emitting device layer disposed on the thin film transistor layer, and a thin film encapsulation layer covering the organic light-emitting device layer, a width of the film-free region of the organic light-emitting device layer is larger than a width of the film-free region of the thin film encapsulation layer.

8. The display panel of claim 7, wherein the width of the film-free region of the thin film encapsulation layer is larger than the width of the film-free region of the thin film transistor layer.

9. The display panel of claim 8, wherein the display panel further comprises a polarizer disposed on the film layers, the polarizer has an opening, an orthographic projection of the opening overlaps with the orthographic projection of the light transmission layer in the direction perpendicular to the display panel, a width of the opening is less than the width of the film-free region of the thin film transistor layer.

10. The display panel of claim 8, wherein the display panel further comprises a substrate with an opening, an orthographic projection of the opening overlaps with the orthographic projection of the light transmission layer in the direction perpendicular to the display panel, a width of the opening is less than the width of the film-free region of the thin film transistor layer.

11. The display panel of claim 7, wherein the thin film transistor layer comprises at least one metal layer, the metal layer bypasses a region corresponding to the light transmission region to form the film-free region of the thin film transistor layer.

12. The display panel of claim 4, wherein the display panel further comprises a plate covering the film layers.

13. A display device, comprising:
the display panel in claim 4; and
a functional device disposed on a non-light-emitting side of the display panel, wherein the functional device has a daylighting region at a side of the functional device toward the display panel, the orthographic projection of the light transmission region overlaps with an orthographic projection of the daylighting region in the direction perpendicular to the display panel.

14. The display device of claim 13, wherein the film layer having the film-free region is an organic light-emitting device layer.

15. The display device of claim 13, wherein the film layers having the film-free region comprise an organic light-emitting device layer and a thin film encapsulation layer covering the organic light-emitting device layer, a width of the film-free region of the organic light-emitting layer is larger than a width of the film-free region of the thin film encapsulation layer.

16. The display device of claim 13, wherein the film layers having the film-free region comprise a thin film transistor layer, an organic light-emitting device layer disposed on the thin film transistor layer, and a thin film encapsulation layer covering the organic light-emitting device layer, a width of the film-free region of the organic light-emitting device layer is larger than a width of the film-free region of the thin film encapsulation layer.

17. The display device of claim 16, wherein the width of the free-film region of the thin film encapsulation layer is larger than the width of the free-film region of the thin film transistor layer.

18. The display panel of claim 17, wherein the display panel further comprises a polarizer disposed on the film layers, the polarizer has an opening, an orthographic projection of the opening overlaps with the orthographic projection of the light transmission region in the direction perpendicular to the display panel, a width of the opening is less than the width of the free-film region of the thin film transistor layer.

19. The display panel of claim 17, wherein the display panel further comprises a substrate with an opening, an orthographic projection of the opening overlaps with the orthographic projection of the light transmission region in the direction perpendicular to the display panel, a width of the opening is less than the width of the free-film region of the thin film transistor layer.

20. The display panel of claim 16, wherein the thin film transistor layer comprises at least one metal layer, the metal layer bypasses a region corresponding to the light transmission region to form the free-film region of the thin film transistor layer.
